(19) United States
(12) Patent Application Publication
(10) Pub. No.: US 2026/0236112 A1
(43) Pub. Date: Aug. 13, 2026

(54) ELECTRONIC PEN

(71) Applicant: Wacom Co., Ltd., Saitama (JP)

(72) Inventors: Kenichi NINOMIYA, Saitama (JP); Mamoru OGATA, Saitama (JP)

(73) Assignee: Wacom Co., Ltd., Saitama (JP)

(21) Appl. No.: 19/639,905

(22) Filed: Apr. 6, 2026

Related U.S. Application Data
(63) Continuation of application No. PCT/JP2024/025214, filed on Jul. 12, 2024.

(30) Foreign Application Priority Data
Oct. 12, 2023 (JP) 2023-176358

(51) Int. Cl. G06F 3/0354; G06F 3/041; H05K 5/00; H05K 5/02

(52) U.S. Cl. CPC G06F 3/03545; G06F 3/0414; G06F 3/04162; H05K 5/0086; H05K 5/0217

(57) ABSTRACT

An electronic pen includes a pen case formed by a tubular front end side case and a tubular tail end side case that are formed of resin being coupled in an axial direction. The electronic pen includes a first functional unit for position indication provided inside the front end side case, a second functional unit provided inside the tail end side case, and a tubular coupling member that has one side in an axial direction being inserted to a coupling side of the front end side case to be coupled with the tail end side case and the other side in the axial direction being inserted to a coupling side of the tail end side case to be coupled with the front end side case to couple the front end side case and the tail end side case together and form the pen case.

### BACKGROUND

### Technical Field

The present disclosure relates to an electronic pen having a pen case formed by a tubular front end side case and a tubular tail end side case being coupled in an axial direction.

### Description of the Related Art

An electronic pen including a position indicator as a first functional unit on a front end side (pen tip side) of a tubular pen case and a position indicator as an example of a second functional unit on a tail end side that is opposite the pen tip side in the axial direction is known. (see Japanese Patent Laid-open No. Hei 8-335132 (hereinafter referred to as “Patent Document 1)). In the electronic pen (stylus pen) described in Patent Document 1, the position indicator as the first functional unit is configured to be used for writing input, while the position indicator as an example of the second functional unit is configured to be used for erasing.

Since this type of electronic pen has a functional unit on both the front end side and the tail end side (the position indicator on both sides in Patent Document 1), its pen case is divided into two, i.e., a front end side case and a tail end side case, in the axial direction. Further, one of the front end side case and the tail end side case has an extended portion which has an outer diameter that corresponds to an inner diameter of the other one of the front end side case and the tail end side case, and the extended portion is press-fitted or screwed to a hollow portion of the other one of the front end side case and the tail end side case, so that the front end side case and the tail end side case are coupled.

Recent electronic pens are becoming thinner and thinner. To thin down an electronic pen, it is advantageous if the front end side case and the tail end side case constituting the pen case are formed by a thin-wall tube. However, when the front end side case and the tail end side case are formed by a thin-wall tube, the coupling portion of the two members in the pen case may become vulnerable in resistance to external force in a direction of crossing the axial direction, posing the risk of cracking.

Further, since the front end side case and the tail end side case are formed of resin, when there is tolerance in the configuration of the coupling portion between the two cases, stress is applied to the coupling portion, and such stress also poses the risk of cracks being generated in the coupling portion.

### BRIEF SUMMARY

The present disclosure provides an electronic pen for the above problems.

Provided is an electronic pen including a pen case formed by a tubular front end side case formed of resin and a tubular tail end side case formed of resin being coupled in an axial direction. The electronic pen includes a first functional unit for position indication provided inside the front end side case, a second functional unit provided inside the tail end side case, and a coupling member that has a tubular shape having a predetermined length in an axial direction. The coupling member has one side in the axial direction being inserted to a coupling side of the front end side case to be coupled with the tail end side case and the other side in the axial direction being inserted to a coupling side of the tail end side case to be coupled with the front end side case to couple the front end side case and the tail end side case together and form the pen case.

According to the electronic pen having the configuration described above, the pen case is formed by the front end side case and the tail end side case being coupled where one side in the axial direction of the tubular coupling member having a predetermined length in the axial direction is inserted into the coupling side of the front end side case to be coupled with the tail end side case and the other side in the axial direction of the coupling member is inserted into the coupling side of the tail end side case to be coupled with the front end side case.

Accordingly, the pen case of the electronic pen having the configuration described is obtained by coupling the two members, i.e., the front end side case and the tail end side case, but is reinforced by the coupling member and thus has great resistance to external force in the direction of crossing the axial direction.

### BRIEF DESCRIPTION OF THE SEVERAL VIEWS OF THE DRAWINGS

FIGS. 1A and 1B are each a diagram for explaining an outline of an electronic pen according to an embodiment of the present disclosure;

FIG. 2 is a diagram for explaining a configuration of a pen case of the electronic pen according to the embodiment of the present disclosure;

FIGS. 3A through 3C are diagrams for explaining an example of a configuration of a first functional unit of a front end side case of the electronic pen according to the embodiment of the present disclosure;

FIG. 4 is a diagram for explaining an example of a configuration of a second functional unit of a tail end side case of the electronic pen according to the embodiment of the present disclosure;

FIG. 5 is a circuit diagram illustrating an example of a configuration of an electronic circuit of the electronic pen according to the embodiment of the present disclosure;

FIG. 6 is a diagram for explaining a modification of principal parts of the electronic pen according to the embodiment of the present disclosure; and

FIG. 7 is a diagram for explaining another modification of the principal parts of the electronic pen according to the embodiment of the present disclosure.

### DETAILED DESCRIPTION

An electronic pen according to an embodiment of the present disclosure will hereinafter be described with reference to the drawings.

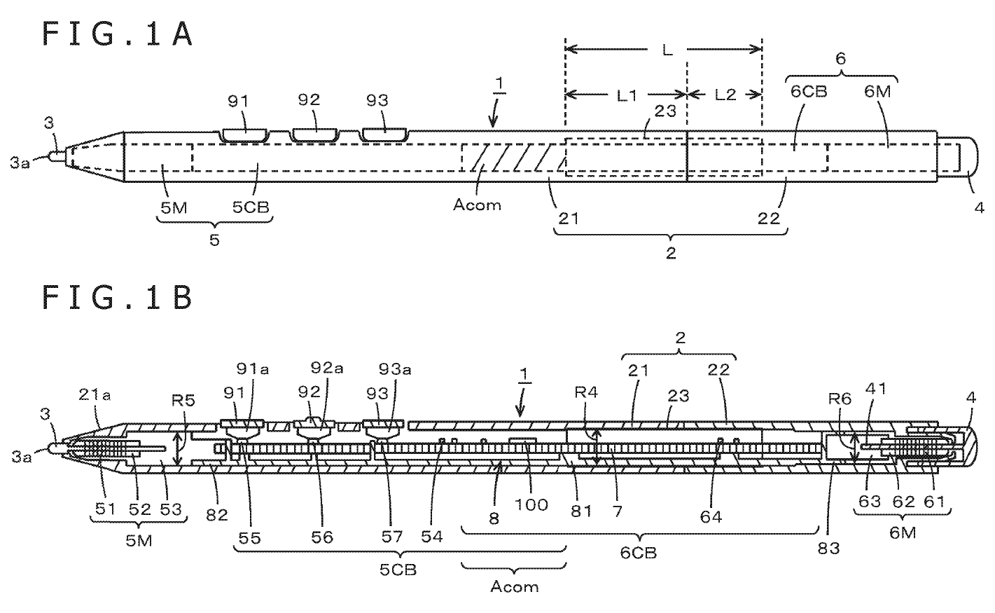

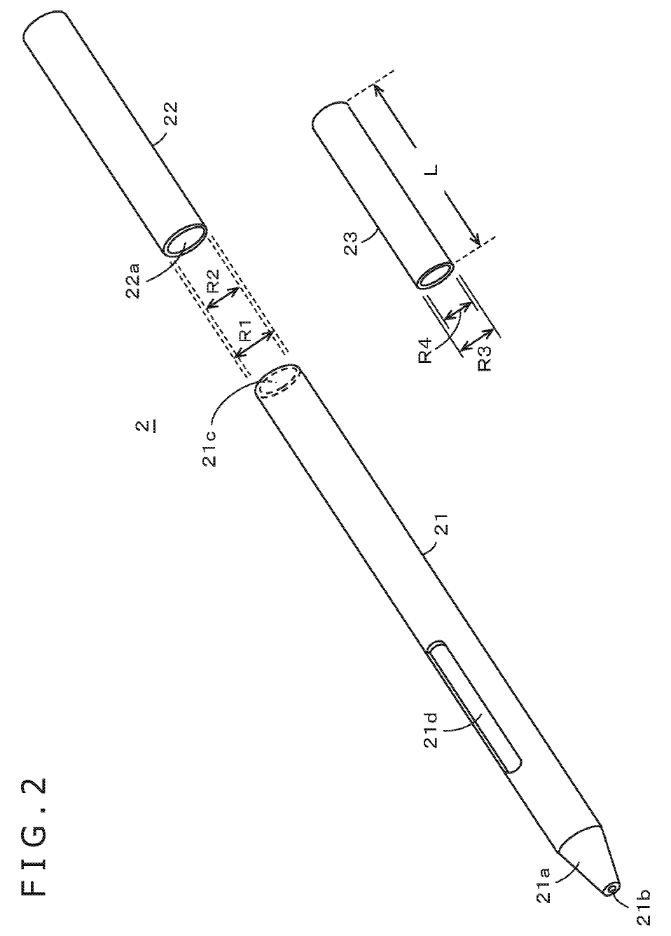

FIG. 1A is an external view of an electronic pen 1 according to the present embodiment, and FIG. 1B is a longitudinal sectional view illustrating an outline of the electronic pen 1. FIG. 2 is an exploded perspective view for explaining a configuration of a pen case 2 of the electronic pen 1 according to the present embodiment. In the following description, in an axial direction of the pen case 2 of the electronic pen 1, a pen tip side is referred to as a front end side, while a side opposite the pen tip side is referred to as a tail end side.

As illustrated in FIGS. 1A through 2, the pen case 2 of the electronic pen 1 according to the present embodiment is formed by a tubular front end side case 21 formed of resin and a tubular tail end side case 22 similarly formed of resin being coupled by a coupling member which is a metal pipe 23 in this example. Note that the coupling member is preferably formed of a material harder than those of the front end side case 21 and the tail end side case 22, and the metal pipe 23 satisfies this condition.

As illustrated in FIGS. 1A through 2, the front end side case 21 includes a tapered portion 21a whose one side in the axial direction serving as the pen tip side of the electronic pen 1 is gradually tapered off, and an opening 21b through which a core body 3 for position indication illustrated in FIG. 1 penetrates is provided in a front end portion of the tapered portion 21a. Further, as illustrated in FIG. 2, the other side in the axial direction of the front end side case 21 is a coupling side to be coupled with the tail end side case 22 and has an opening 21c. Further, in the present embodiment, at a predetermined position in the axial direction of the front end side case 21, a through hole 21d for providing operators 91, 92, and 93 (see FIG. 1A) for three switches (side switches) 55, 56, and 57 to be described later is formed.

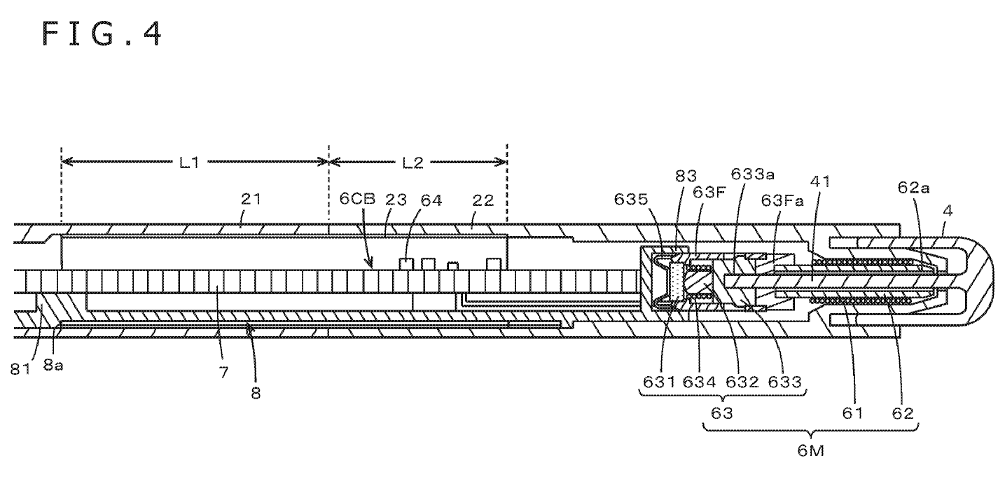

Moreover, as illustrated in FIG. 2, one side in the axial direction of the tail end side case 22 is a coupling side to be coupled with the front end side case 21 and has an opening 22a. The tail end side case 22 has a tail end cap member 4 mounted on the other side (tail end side) in the axial direction, as illustrated in FIG. 4 described later.

As illustrated in FIG. 2, an outer diameter of the front end side case 21 except the tapered portion 21a on the pen tip side is a fixed diameter R1 in the present embodiment. Moreover, in the present embodiment, an outer diameter of the tail end side case 22 is also the fixed diameter R1 equal to the outer diameter of the front end side case 21. Further, in the present embodiment, as illustrated in FIG. 2, an inner diameter of the opening 21c on the coupling side of the front end side case 21 to be coupled with the tail end side case 22 and an inner diameter of the opening 22a on the coupling side of the tail end side case 22 to be coupled with the front end side case 21 are equally a diameter R2.

In the present embodiment, as illustrated in FIG. 2, the metal pipe 23 is a tubular member having a predetermined length L in the axial direction and having a fixed outer diameter and inner diameter in the axial direction. Further, in the present embodiment, the metal pipe 23 used is thin and has a thickness d that is d = 0.15 mm in the present example. A thin metal pipe 23 is used for taking thinning down of the electronic pen 1 into consideration.

According to the present embodiment, the outer diameter of the metal pipe 23 is a diameter R3 that is equal to or slightly smaller than the inner diameter R2 of the opening 21c and the opening 22a on the coupling sides of the front end side case 21 and the tail end side case 22. A value of the outer diameter R3 of the metal pipe 23 is one by which one end side of the metal pipe 23 in the axial direction is inserted or press-fitted in this example into the front end side case 21 in a state of being in contact with an inner surface on the coupling side of the front end side case 21 from the opening 21c on the coupling side of the front end side case 21 and the other end side of the metal pipe 23 in the axial direction is inserted or press-fitted in this example into the tail end side case 22 in a state of being in contact with an inner wall surface on the coupling side of the tail end side case 22.

According to the present embodiment, according to a length of the front end side case 21 in the axial direction being longer than a length of the tail end side case 22 in the axial direction, as illustrated in FIG. 1A, a portion of a length L1 on one end side in the axial direction of the metal pipe 23 having the length L1 is inserted into the front end side case 21, while a portion of a remaining length L2 (< L1) is inserted into the tail end side case 22. As illustrated in FIG. 1A, when an end surface of the opening 21c on the coupling side of the front end side case 21 and an end surface of the opening 22a on the coupling side of the tail end side case 22 are butted against each other, the front end side case 21 and the tail end side case 22 are coupled. Note that, instead of having the end surface of the opening 21c on the coupling side of the front end side case 21 and the end surface of the opening 22a on the coupling side of the tail end side case 22 butted against each other, a ring-shaped member may be sandwiched between the end surface of the opening 21c on the coupling side of the front end side case 21 and the end surface of the opening 22a on the coupling side of the tail end side case 22.

Note that, in order to more reliably have the portion of the length L1 of the metal pipe 23 fitted to the coupling side of the front end side case 21, a ring-shaped protrusion may be provided on the inner wall surface within the length L1 on the coupling side of the front end side case 21, while a recessed groove that engages with the ring-shaped protrusion of the front end side case 21 when the metal pipe 23 is inserted to the coupling side of the front end side case 21 for the length L1 may be provided on an outer peripheral portion of the metal pipe 23. As a result, when the portion of the length L1 of the metal pipe 23 is fitted to the coupling side of the front end side case 21, the ring-shaped protrusion and the recessed groove are engaged with each other and locked in what is generally called a clicking manner. Similarly, the fitting of the portion of the length L2 of the metal pipe 23 with the coupling side of the tail end side case 22 may be performed with a configuration of forming a ring-shaped protrusion and a recessed groove.

Inside the pen case 2 of the electronic pen 1 according to the present embodiment, as illustrated in outline by a dotted line in FIG. 1A, a first functional unit 5 is provided in the front end side case 21, while a second functional unit 6 is provided in the tail end side case 22. The first functional unit 5 includes a first main part 5M and a first circuit board section 5CB, while the second functional unit 6 includes a second main part 6M and a second circuit board section 6CB.

As illustrated in FIG. 1A, the first main part 5M and the first circuit board section 5CB of the first functional unit 5 are arranged side by side in an axial direction inside the front end side case 21 where the first main part 5M is on the front end side (pen tip side). Moreover, similarly, as illustrated in FIG. 1A, the second main part 6M and the second circuit board section 6CB of the second functional unit 6 are arranged side by side in an axial direction inside the tail end side case 22 where the second main part 6M is on the tail end side.

Further, in the present embodiment, the first circuit board section 5CB and the second circuit board section 6CB are arranged on a single common circuit board 7. As illustrated in FIG. 1B, the circuit board 7 is mounted and held on a circuit board mounting section 81 of a board holder 8 formed of resin, for example.

The board holder 8 is longer than the front end side case 21 or the tail end side case 22 in a direction that is the axial direction of the pen case 2 when the board holder 8 is housed inside the hollow portion of the pen case 2, and has a boat shape having a length extending from the hollow portion of the front end side case 21 to the hollow portion of the tail end side case 22 in the hollow portion of the pen case 2. A portion of the board holder 8 corresponding to the circuit board mounting section 81 has a curved surface portion that lies along a substantially semi-circumference portion on an inner wall surface of the cylindrical hollow portion of the pen case 2 and a planar portion including a straight line connecting end edges of the curved surface portion. The circuit board mounting section 81 is formed on that planar portion. Further, the board holder 8 in the present embodiment has, as described later, a tubular pressure detector holding section 82 on the front end side (pen tip side) and a tubular pressure detector holding section 83 on the tail end side in the axial direction (longitudinal direction) together with the circuit board mounting section 81 in an integrated manner.

Note that the present embodiment includes a common area portion Acom in which the first circuit board section 5CB and the second circuit board section 6CB partly overlap in the longitudinal direction of the circuit board 7. In this common area portion Acom in the present example, a control circuit integrated circuit (IC) 100 (see FIG. 1B) that has a function of controlling the first functional unit 5 and the second functional unit 6 is provided. The circuit configuration of the first functional unit 5 and the second functional unit 6 as well as the control circuit IC 100 is described later.

The first functional unit 5 is a functional unit for position indication used for writing input or position indication input by the electronic pen 1. In the present embodiment, the first main part 5M of the first functional unit 5 is configured to perform signal interaction with a position detection sensor by an electromagnetic induction system, and includes a member in which a coil 51 is wound around a magnetic core which is a ferrite core 52 in this example and a pressure detector 53.

As illustrated in FIG. 1B, in the present embodiment, the board holder 8 has the pressure detector holding section 82 that is formed in an integrated manner with the circuit board mounting section 81 on the front end side (pen tip side), and holds the pressure detector 53 by the pressure detector holding section 82. Further, the ferrite core 52 around which the coil 51 is wound is held by the pressure detector 53.

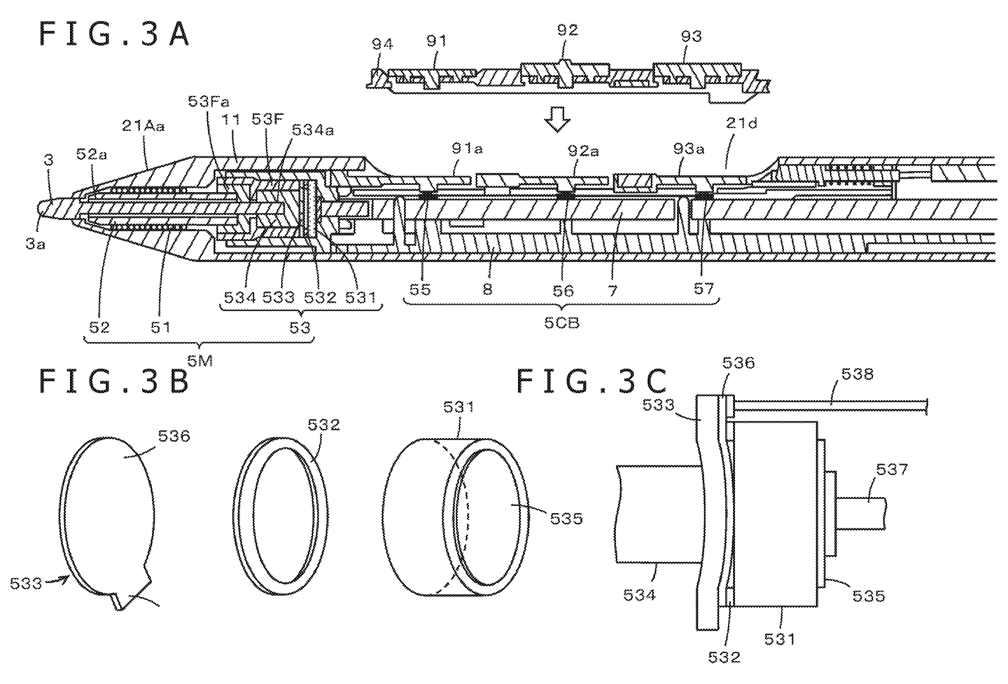

FIG. 3A is an enlarged cross sectional view of the front end side of the electronic pen 1, FIG. 3B is an exploded perspective view of the main components of the pressure detector 53 in the present example, and FIG. 3C is a diagram for explaining a pressure detection operation of the pressure detector 53.

As illustrated in FIG. 3A, the ferrite core 52 is provided with a through hole 52a in the axial direction. Further, the core body 3 formed to have a rod shape is inserted from the opening 21b of the front end side case 21 into the front end side case 21 in such a manner as to penetrate the through hole 52a, and a rear end side of the core body 3 is fitted to the pressure detector 53. At this time, a front end portion 3a of the core body 3 is in a state of protruding outward from the opening 21b of the front end side case 21.

The pressure detector 53 in the present embodiment is configured as a variable capacitance capacitor that detects the pressure (pen pressure) applied to the core body 3 as a change in capacitance. As illustrated in FIG. 3A, the pressure detector 53 has pressure detection components arranged inside a holder 53F made of resin. Further, on a front end side of the holder 53F, a cap portion 53Fa is provided, and holds the rear end side of the ferrite core 52.

As illustrated in FIGS. 3A, 3B, and 3C, the pressure detection components of the pressure detector 53 in the present example include a dielectric 531, a spacer 532, an elastic member 533, and a pusher member 534 constituting a pressure transmitting member. The dielectric 531 has a circular plate shape having a predetermined diameter, and is provided with a first electrode 535 on one of circular flat surfaces facing each other via a thickness portion, as illustrated in FIG. 3B.

The spacer 532 is constituted by an insulating material and is formed in a ring shape having an outer diameter equal to the diameter of the dielectric 531 in this example. The elastic member 533 is formed of an elastic material, for example, elastic rubber, and has a thin circular plate shape having a diameter equal to or greater than the diameter of the dielectric 531. Over an entire surface of one of the circular flat surfaces of the elastic member 533, a second electrode 536 is formed. As illustrated in FIG. 3A, the pusher member 534 includes a fitting portion 534a on the rear end side of the core body 3, and a front end side opposite the fitting portion 534a in the axial direction has a shape bulging in a dome shape.

Further, as illustrated in FIGS. 3A and 3B, the elastic member 533 is arranged via the spacer 532 on the other circular flat surface side facing the one circular flat surface side via the thickness portion of the dielectric 531. In this case, the circular flat surface side of the elastic member 533 on which the second electrode 536 is formed is arranged to face the other circular flat surface of the dielectric 531 via the spacer 532. In this way, the first electrode 535 formed on one circular flat surface of the dielectric 531 and the second electrode 536 formed on the circular flat surface of the elastic member 533 face each other with the dielectric 531 sandwiched therebetween, forming a capacitor.

Further, as illustrated in FIGS. 3A and 3C, the pusher member 534 is arranged in such a manner as to press the elastic member 533 by the dome-shaped bulging portion on the front end side. Accordingly, when pressure (pen pressure) is applied to the front end portion 3a of the core body 3 the rear end side of which is fitted to the pusher member 534, the elastic member 533 is pressed by the pusher member 534, and a portion of the elastic member 533 corresponding to the opening portion of the ring-shaped spacer 532 is elastically displaced as illustrated in FIG. 3C. As a result of this elastic displacement, the second electrode 536 formed on the circular flat surface of the elastic member 533 comes into contact with the other circular flat surface of the dielectric 531.

In this case, the area in which the second electrode 536 is in contact with the other circular flat surface of the dielectric 531 depends on the press force of the pusher member 534, that is, the pressure (pen pressure) applied to the front end portion 3a of the core body 3. Hence, the capacity of the capacitor formed between the first electrode 535 and the second electrode 536 with the dielectric 531 sandwiched therebetween changes according to the area of contact between the second electrode 536 and the other circular flat surface of the dielectric 531. Accordingly, detecting the capacitance of the capacitor allows the pen pressure applied to the front end portion 3a of the core body 3 to be detected.

As illustrated in FIG. 3C, in the pressure detector 53, a first terminal 537 is provided for the first electrode 535, and is electrically connected to the first circuit board section 5CB of the circuit board 7. Further, a second terminal 538 is provided for the second electrode 536, and is electrically connected to the first circuit board section 5CB of the circuit board 7.

The first circuit board section 5CB is provided with a capacitor 54 that is connected in parallel to the coil 51 and thereby constitutes a resonant circuit. The control circuit IC 100 in the common area portion Acom described above controls the resonant circuit to transmit (feed back) a signal for detecting a writing input position to the position detection sensor side, detects the capacitance of the pressure detector 53 to generate information regarding a pressure value (pen pressure value), and thereby transmits the generated information regarding the pressure value (pen pressure value) to the position detection sensor side.

The pressure detector 53 of the first main part 5M of the first functional unit 5 has the configuration illustrated in FIGS. 3A through 3C, and can thus detect the pressure value (pen pressure value) at high accuracy and with high sensitivity. In the present embodiment, the pressure detector 53 is configured to detect the pressure value (pen pressure value) at an accuracy of equal to or higher than 4K (4096) levels of pen pressure sensitivity in the control circuit IC 100. The diameter of the dielectric 531 of the pressure detector 53 in this example is set to be greater than the diameter of a dielectric 631 of a pressure detector 63 of the second main part 6M of the second functional unit 6 to be described later, to allow the pressure value (pen pressure value) to be detected at a high level of pen pressure sensitivity.

Moreover, in the present embodiment, the first circuit board section 5CB is provided with the three switches (side switches) 55, 56, and 57, which are each configured to be turned on/off by a pressing operation on the respective operators 91, 92, and 93 provided on a side surface of the front end side case 21, as illustrated in FIG. 1A. The control circuit IC 100 in the common area portion Acom described above monitors the on/off state of the switches 55, 56, and 57, and transmits information regarding the on/off state of the switches 55, 56, and 57 to the position detection sensor side.

The position detection sensor side is configured to execute and control the functions assigned in advance to the switches 55, 56, and 57, based on the information regarding the on/off state of the switches 55, 56, and 57. Functions assigned in advance to the switches 55, 56, and 57 are, for example, in a state in which the first functional unit 5 is interacting with the position detection sensor, a function corresponding to a left click or a right click of a mouse, a function of selecting the width, thickness, color, or type of the line input by writing, and the like.

The switches 55, 56, and 57 are switches of a type that is turned on/off in response to receiving a pressing operation. As illustrated in FIG. 3A, the operators 91, 92, and 93 are arranged on an attachment plate 94 attached to the through hole 21d provided on an upper position of the switches 55, 56, and 57 disposed on the circuit board 7, on the side surface of the front end side case 21. With the intervention of pressing transmitters 91a, 92a, and 93a provided between the operators 91, 92, and 93 and the switches 55, 56, and 57, the switches 55, 56, and 57 are turned on and off by the pressing operation on the operators 91, 92, and 93.

In the present embodiment, as illustrated in FIGS. 1A and 1B, the positions of the switches 55, 56, and 57 and the operators 91, 92, and 93 in the axial direction of the pen case 2 of the electronic pen 1 do not overlap the metal pipe 23. In this example, the operators 91, 92, and 93 and the switches 55, 56, and 57 are arranged on the front end side relative to the length L1 for which the metal pipe 23 as the coupling member is inserted into the front end side case 21, in the axial direction of the front end side case 21.

Hence, the portion of the length L1 of the metal pipe 23 as the coupling member is inserted into the front end side case 21 without being obstructed by the presence of the switches 55 through 57 and the pressing transmitters 91a through 93a provided directly below the operators 91 through 93. The portion of the length L1 of the metal pipe 23 can be extended to the positions of the switches 55 through 57 and the operators 91 through 93, but in that case, the metal pipe 23 needs to be processed so as to avoid the operators 91 through 93 and the pressing transmitters 91a through 93a. In this regard, selecting the length L1 of the metal pipe 23 in such a manner as to obtain the positional relation according to the present embodiment has such an advantage that the abovementioned processing need not be performed.

Next, the second functional unit 6 in the present embodiment is formed as a functional unit for position indication used for erasing a writing trace input by the first functional unit 5. Further, in the present embodiment, the second main part 6M of the second functional unit 6 also performs signal interaction with the position detection sensor by an electromagnetic induction system, and includes a member in which a coil 61 is wound around a magnetic core which is a ferrite core 62 in this example and a pressure detector 63.

As illustrated in FIG. 1B, in the present embodiment, the board holder 8 has, on the tail end side, the pressure detector holding section 83 that is formed in an integrated manner with the circuit board mounting section 81, and holds the pressure detector 63 by the pressure detector holding section 83. Further, the ferrite core 62 around which the coil 61 is wound is configured to be held by the pressure detector 63.

FIG. 4 is an enlarged cross sectional view of the tail end side of the electronic pen 1. As illustrated in FIG. 4, the ferrite core 62 is provided with a through hole 62a in the axial direction. As illustrated in FIG. 1B, a pressure transmitting rod-shaped member 41 provided on the tail end cap member 4 is inserted into the ferrite core 62 in such a manner as to penetrate the through hole 62a from an opening on the tail end side of the tail end side case 22, and a front end side of the pressure transmitting rod-shaped member 41 of the tail end cap member 4 is fitted to the pressure detector 63. As a result, the pressure applied to the tail end cap member 4 is transmitted to the pressure detector 63, and the pressure detector 63 detects the applied pressure.

Similarly to the pressure detector 53, in the present embodiment, the pen pressure detector 63 is configured as a variable capacitance capacitor that detects the pressure applied to the tail end cap member 4 as a change in capacitance. However, the pressure detector 63 has a simpler configuration unlike the pressure detector 53.

As illustrated in FIG. 4, the pressure detector 63 has pressure detection components arranged inside a holder 63F made of resin. Note that a cap portion 63Fa is provided on the tail end side of the holder 63F, and holds an end portion of the ferrite core 62 on a side opposite the tail end side.

As illustrated in FIG. 4, the pressure detection components of the pressure detector 63 include, in this example, the dielectric 631, a conductive elastic member 632, a pusher member 633 constituting the pressure transmitting member, and a returning spring member 634. The dielectric 631 has a circular plate shape having a predetermined diameter and has a first electrode provided on one of circular flat surfaces facing each other via the thickness portion. Further, a first terminal 635 electrically connected to the first electrode formed on the dielectric 631 is provided and is connected to the second circuit board section 6CB of the circuit board 7.

The conductive elastic member 632 has a bullet shape and has a dome-shaped bulging portion on the front end side thereof. The conductive elastic member 632 is arranged in a state in which the dome-shaped bulging portion faces the circular flat surface on a side opposite the side where the first electrode is formed in the dielectric 631 and is movable toward the dielectric 631 side by being pressed by the pusher member 633.

The conductive elastic member 632 is formed by elastic rubber having conductivity in this example and constitutes a second electrode facing the first electrode with the dielectric 631 sandwiched therebetween. In this way, the first electrode formed on one surface side of the dielectric 631 and the second electrode constituted by the conductive elastic member 632 face each other with the dielectric 631 sandwiched therebetween, forming a capacitor. Although omitted from illustration in FIG. 4, the conductive elastic member 632 is electrically connected to the second circuit board section 6CB of the circuit board 7.

The pusher member 633 has a fitting portion 633a to which the pressure transmitting rod-shaped member 41 of the tail end cap member 4 is fitted, on a side opposite the conductive elastic member 632. When pressure is applied to the tail end cap member 4, the pusher member 633 presses the conductive elastic member 632 according to the applied pressure via the pressure transmitting rod-shaped member 41, and the bulging portion on the front end side of the conductive elastic member 632 comes into contact with the dielectric 631.

In this case, the area in which the bulging portion of the conductive elastic member 632 as the second electrode is in contact with the circular flat surface of the dielectric 631 depends on the press force by the pusher member 633, that is, the pressure applied to the tail end cap member 4. Hence, the capacity of the capacitor formed between the first electrode and the conductive elastic member 632 as the second electrode with the dielectric 631 sandwiched therebetween changes according to the area of contact between the conductive elastic member 632 and the circular flat surface of the dielectric 631. Accordingly, detecting the capacitance of the capacitor allows the pressure applied to the tail end cap member 4 to be detected. When the pressure applied to the tail end cap member 4 is extinguished, the conductive elastic member 632 returns to its original state with respect to the dielectric 631 by the elastic force of the returning spring member 634.

As illustrated in FIGS. 1B and 4, the second circuit board section 6CB is provided with a capacitor 64 that is connected in parallel to the coil 61 and thereby constitutes a resonant circuit. The control circuit IC 100 in the common area portion Acom described above controls the resonant circuit to transmit (feed back) a signal for detecting an erasing position to the position detection sensor side, detects the capacitance of the pressure detector 63 to generate information regarding a pressure value, and thereby transmits the generated information regarding the pressure value to the position detection sensor side.

In the present embodiment, the second functional unit 6 is configured as a position indication functional unit for erasing a writing trace, and hence, the pressure detector 63 of the second main part 6M is allowed to detect a pressure value at a lower level of pen pressure sensitivity than the pressure detector 53 of the first main part 5M of the first functional unit 5, which is configured as a position indication functional unit for writing input, and is thus configured as described above. Further, since the pressure value may be detected at a low level of pen pressure sensitivity, the dielectric 631 used for the pressure detector 63 has a diameter smaller than the diameter of the dielectric 531 used in the pressure detector 53.

As illustrated in FIG. 1B, in the electronic pen 1 according to the present embodiment, the maximum inner diameter of the hollow portion of the front end side case 21 and the maximum inner diameter of the hollow portion of the tail end side case 22 are set by taking into consideration the outer diameters of the holder 53F of the pressure detector 53 and the holder 63F of the pressure detector 63. Further, the outer diameters of the holder 53F and the holder 63F correspond to the diameters of particularly the dielectric 531 and the dielectric 631 among the pressure detection components. As described above, in the present embodiment, the diameter of the dielectric 531 is greater than the diameter of the dielectric 631. Hence, as illustrated in FIG. 1B, in the electronic pen 1 according to the present embodiment, a maximum inner diameter R5 of the hollow portion of the front end side case 21 is greater than a maximum inner diameter R6 of the hollow portion of the tail end side case 22.

The outer diameter of the front end side case 21 can be set by adding a thickness obtained by taking into consideration the strength of the front end side case 21 to the maximum inner diameter R5. While the outer diameter of the tail end side case 22 can be set in a similar manner, since the maximum inner diameter R6 of the tail end side case 22 is smaller than the maximum inner diameter R5 of the front end side case 21, the thickness of the tail end side case 22 can have a margin.

In other words, in the present embodiment, the outer diameter of the electronic pen 1 can be set according to such an inner diameter that the pressure detector 53 of the first functional unit 5 can be housed in the front end side case 21, and the diameter of the tail end side case 22 need not be taken into consideration, offering more advantages in design.

Note that, in the electronic pen 1 according to the present embodiment, as is obvious from the description above, an electronic pen body (configuration including the first functional unit 5, the second functional unit 6, and the circuit board 7) that is to be housed in the pen case 2 is unitized by the circuit board 7 being held on the board holder 8, the first main part 5M of the first functional unit 5 being held on the pen tip side of the board holder 8, and the second main part 6M of the second functional unit 6 being held on the tail end side.

That is, the first main part 5M of the first functional unit 5 includes the pressure detection components of the pressure detector 53 held on the holder 53F, and the ferrite core 52 around which the coil 51 is wound is held on the holder 53F. Further, the holder 53F is held on the pressure detector holding section 82 provided on the pen tip side of the board holder 8. Similarly, the second main part 6M of the second functional unit 6 includes the pressure detection components of the pressure detector 63 held on the holder 63F, and the ferrite core 62 around which the coil 61 is wound is held on the holder 63F. Further, the holder 63F is held on the pressure detector holding section 83 provided on the tail end side of the board holder 8.

Accordingly, the electronic pen 1 can be assembled by, before the front end side case 21 and the tail end side case 22 are coupled via the metal pipe 23 to generate the pen case 2, housing the unitized electronic pen body in one of the front end side case 21 and the tail end side case 22, coupling the front end side case 21 and the tail end side case 22 with use of the metal pipe 23 in that state, and thereafter attaching the core body 3 and the tail end cap member 4.

In this case, the unit of the electronic pen body may be inserted into the front end side case 21 or the tail end side case 22 in a state in which the metal pipe 23 is inserted into the front end side case 21 or the tail end side case 22 and the front end side case 21 and the tail end side case 22 are coupled in advance, or the metal pipe 23 may be inserted into the front end side case 21 or the tail end side case 22 after the unit of the electronic pen body has been inserted in advance into the front end side case 21 or the tail end side case 22.

Yet, in a case of assembling the electronic pen 1 by a method of inserting in advance the metal pipe 23 into the front end side case 21 or the tail end side case 22, the inner diameter R4 of the metal pipe 23 needs to be greater than the outer diameter of the holder 53F of the pressure detector 53. In view of this, in the present embodiment, the inner diameter R4 of the metal pipe 23 is selected to be greater than the maximum inner diameter R5 of the front end side case 21. This allows the electronic pen 1 to be assembled by either of the steps of assembling described above.

Further, in the case of adopting the assembly method of inserting the unit of the electronic pen body into the front end side case 21 or the tail end side case 22 in advance and thereafter inserting the metal pipe 23 into the front end side case 21 or the tail end side case 22, the metal pipe 23 can be formed to be used as such a position restricting member that the unit of the electronic pen body inserted into the front end side case 21 or the tail end side case 22 does not move in the axial direction.

That is, for example, the board holder 8 of the unit of the electronic pen body is to be formed with a step portion that engages with one or the other one of the end edges of the metal pipe 23 in the axial direction when the board holder 8 is inserted into the front end side case 21 or the tail end side case 22, and that restricts the position such that the board holder 8 does not move in the axial direction when inserted into the front end side case 21 or the tail end side case 22. FIG. 4 illustrates a step portion 8a of the board holder 8 that engages with the end edge of the portion of the length L1 of the metal pipe 23.

As a result, for example, when the metal pipe 23 is inserted into the front end side case 21 for the length L1 after the unit of the electronic pen body has been inserted in advance into the front end side case 21, the step portion 8a of the board holder 8 of the unit of the electronic pen body and the end edge of the metal pipe 23 in the axial direction engage with each other when the end portion on the pen tip side of the pressure detector holding section 82 of the board holder 8 or the end portion on the pen tip side of the holder 53F, for example, of the unit of the electronic pen body collides with the pen tip side of the hollow portion of the front end side case 21, and the unit of the electronic pen body is restricted in position in the axial direction inside the front end side case 21. By the portion of the length L2 of the metal pipe 23 being inserted into the tail end side case 22 from this state, the electronic pen 1 can easily be assembled.

Alternatively, when the metal pipe 23 is inserted into the tail end side case 22 for the length L2 after the unit of the electronic pen body has been inserted in advance into the tail end side case 22, the step portion 8a of the board holder 8 of the unit of the electronic pen body and the end edge of the metal pipe 23 in the axial direction engage with each other when the end portion on the tail end side of the pressure detector holding section 83 of the board holder 8 or the end portion on the tail end side of the holder 63F, for example, of the unit of the electronic pen body collides with the tail end side of the hollow portion of the tail end side case 22, and the unit of the electronic pen body is restricted in position in the axial direction inside the tail end side case 22. By the portion of the length L1 of the metal pipe 23 being inserted into the front end side case 21 from this state, the electronic pen 1 can easily be assembled.

This offers an advantage of allowing the metal pipe 23 to function as a position restricting member for the unit of the electronic pen body in the axial direction in the pen case 2 and also making it easier to assemble the electronic pen 1.

### Description of Circuit Configuration Example of Electronic Pen 1

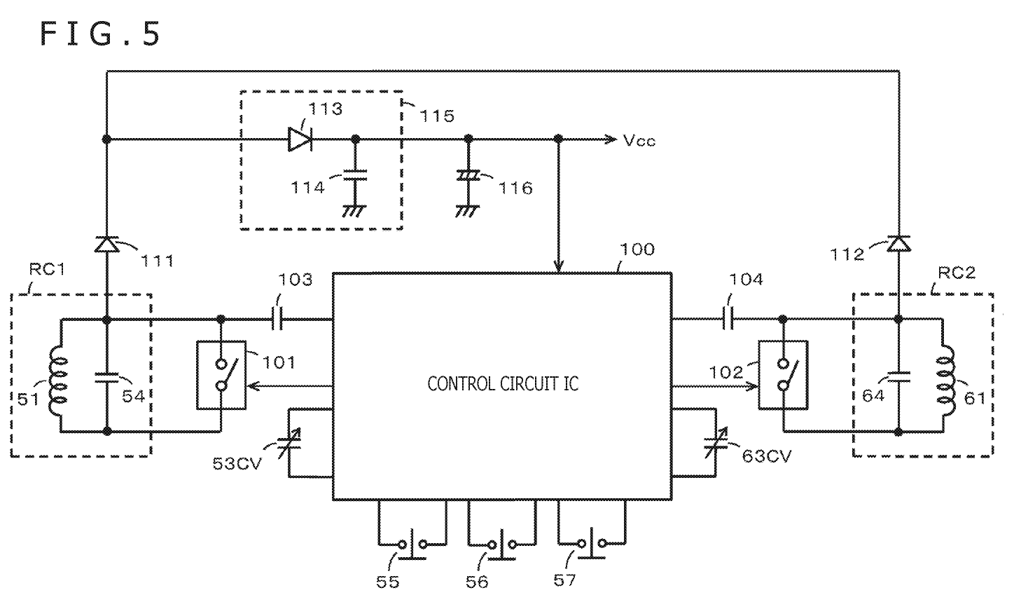

Next, an example of a configuration of an electronic circuit formed on the circuit board 7 of the electronic pen 1 according to the present embodiment is described. FIG. 5 is a diagram illustrating an example of a circuit configuration of the electronic pen 1.

The first functional unit 5 and the second functional unit 6 of the electronic pen 1 are configured to perform interaction with the position detection sensor by electromagnetic induction coupling with a loop coil group of the position detection sensor, exchange position detection signals for writing input and position detection signals for erasing, and transmit additional information such as information regarding the pressure value detected through the pressure detector 53 and the pressure detector 63 and information regarding the on/off state of the switches 55, 56, and 57 to the position detection sensor.

As described above, the electronic pen 1 according to the present embodiment includes the control circuit IC 100 that controls in common the first functional unit 5 and the second functional unit 6, as illustrated in FIG. 5. Moreover, as illustrated in FIG. 5, the coil 51 of the first main part 5M of the first functional unit 5 is connected in parallel to the capacitor 54 of the first circuit board section 5CB and thereby constitutes a first resonant circuit R1. Similarly, the coil 61 of the second main part 6M of the second functional unit 6 is connected in parallel to the capacitor 64 of the second circuit board section 6CB and thereby constitutes a second resonant circuit RC2. In the present embodiment, the first resonant circuit RC1 and the second resonant circuit RC2 have different resonance frequencies.

The position detection sensor side monitors the frequency of the signal transmitted (fed back) from the electronic pen 1, to determine whether the first functional unit 5 of the electronic pen 1 is interacting with the position detection sensor or the second functional unit 6 is interacting with the position detection sensor. According to the result of the determination, the position detection sensor performs switching control to switch the frequency of the signal to be transmitted to the electronic pen 1 from the loop coil group of the position detection sensor to a frequency equal to the resonance frequency of the first resonant circuit RC1 or a frequency equal to the resonance frequency of the second resonant circuit RC2.

Note that any one of the switches 55, 56, and 57 of the electronic pen 1 may be used as a switch for switching between the first functional unit 5 and the second functional unit 6, and the position detection sensor side may switch the signal to be sent out to a frequency equal to the resonance frequency of the first resonant circuit RC1 or a frequency equal to the resonance frequency of the second resonant circuit RC2, based on information regarding the on/off state of that switch. In that case, the position detection sensor side is configured to monitor the on/off state of the switch that is assigned with a switching control function and switch the frequency of the signal to be transmitted to the electronic pen 1 from the loop coil group of the position detection sensor to a frequency equal to the resonance frequency of the first resonant circuit RC1 or a frequency equal to the frequency of the second resonant circuit RC2 according to the result of monitoring.

Further, in this example, switches 101 and 102 are each connected in parallel to the respective resonant circuits RC1 and RC2. These switches 101 and 102 are controlled to be turned on/off by the control circuit IC 100, and the resonance operations of the resonant circuits RC1 and RC2 are controlled to be turned on/off by the control circuit IC 100. That is, when the switches 101 and 102 are turned off, the resonant circuits RC1 and RC2 can perform resonance operations with respect to the signal from the position detection sensor. However, when the switches 101 and 102 are turned on, the capacitors 54 and 64 respectively connected in parallel to the coils 51 and 61 are short-circuited, so that the resonance operations by the resonant circuits RC1 and RC2 with respect to the signal from the position detection sensor are turned off.

In the present embodiment, as a result of the control of turning on/off the resonant circuits RC1 and RC2 by the control circuit IC 100, additional information such as the information regarding the pressure values detected by the pressure detectors 53 and 63 and the on/off of the switches 55, 56, and 57 is transmitted from the electronic pen 1 to the position detection sensor side, as information regarding a plurality of bits of digital signal.

Further, in the present embodiment, alternating current signals received through electromagnetic coupling by the resonant circuits RC1 and RC2 from the position detection sensor are supplied to the control circuit IC 100 via the respective capacitors 103 and 104. The control circuit IC 100 detects signal interaction between the first functional unit 5 and the position detection sensor or signal interaction between the second functional unit 6 and the position detection sensor, by the alternating current signals input through the capacitors 103 and 104.

Further, in the present embodiment, the alternating current signals received through electromagnetic coupling by the resonant circuits RC1 and RC2 from the position detection sensor are supplied via backflow preventing diodes 111 and 112 to a rectifier circuit 115 including a rectifying diode 113 and a capacitor 114 and rectified. Further, by a rectified output current from the rectifier circuit 115, a capacitor 116 for charging is charged. The charged voltage of the capacitor 116 is supplied to the control circuit IC 100 as a power supply voltage Vcc.

Further, to the control circuit IC 100, a variable capacitance capacitor 53CV including the pressure detector 53 of the first main part 5M of the first functional unit 5 and a variable capacitance capacitor 63CV including the pressure detector 63 of the second main part 6M of the second functional unit 6 are connected.

The control circuit IC 100 measures the capacitance of the variable capacitance capacitors 53CV and 63CV and detects the pressure value from the measured capacitance of the variable capacitance capacitors 53V and 63V. Note that the capacitance of the variable capacitance capacitors 53CV and 63CV can be measured by, for example, having the variable capacitance capacitors 53CV and 63CV discharge and charge and measuring the time of discharge and charge.

In this case, in the present embodiment, the control circuit IC 100 converts the calculated pressure value into pressure data of a digital signal of a plurality of bits that can represent the level of pen pressure sensitivity corresponding to the detection performance of the pressure detector 53 and the pressure detector 63. Thereafter, the control circuit IC 100 performs control of turning on/off the switches 101 and 102 by the pressure data, to transmit the digital signal of the pressure value of a plurality of bits to the position detection sensor as part of additional information including an amplitude shift keying (ASK) signal or an on off keying (OOK) signal.

Further, in this example, the switches 55, 56, and 57 are connected to the control circuit IC 100. Moreover, the control circuit IC 100 monitors the on/off state of the switches 55, 56, and 57 caused by the operation on the operators 91, 92, and 93 and generates information regarding a plurality of bits indicating the on/off state. Further, the control circuit IC 100 performs control of turning on/off the switches 101 and 102 by the generated information regarding a plurality of bits, to transmit the information regarding the on/off state of the switches 55 through 57 to the position detection sensor as part of the additional information including the ASK signal or the OOK signal.

When the first functional unit 5 of the electronic pen 1 is in a state of interacting with the position detection sensor, the control circuit IC 100, for example, repeats a position indication period for writing input and a subsequent additional information sending-out period at a predetermined cycle. Moreover, in the position indication period for writing input, the control circuit IC 100 turns off the switch 101 and receives the signal transmitted from the position detection sensor side by the resonant circuit RC1 to cause the signal to be fed back to the position detection sensor side. Further, in the additional information sending-out period, the control circuit IC 100 turns on/off the switch 101 by the digital signal as the additional information to turn on/off the resonant circuit RC1 and send out the additional information as the ASK signal or the OOK signal.

When the second functional unit 6 is in the state of interacting with the position detection sensor, the control circuit IC 100 similarly repeats a position indication period for erasing and the subsequent additional information sending-out period at a predetermined cycle, for example. Moreover, in the position indication period for erasing, the control circuit IC 100 turns off the switch 102 and receives the signal transmitted from the position detection sensor side by the resonant circuit RC2 to cause the signal to be fed back to the position detection sensor side, while in the additional information sending-out period, turns on/off the switch 102 by the digital signal as the additional information to turn on/off the resonant circuit RC2 and send out the additional information as the ASK signal or the OOK signal.

Note that, in a case where the functions assigned to the switches 55 through 57 are solely for the first functional unit 5, in the additional information sending-out period when the second functional unit 6 is operating, the information regarding the on/off state of the switches 55 through 57 need not be included in the additional information. Yet, in a case where one of the switches 55 through 57 is to be used for switching between the first functional unit 5 and the second functional unit 6, information regarding the on/off state of the switch for switching is included in the additional information. Moreover, the switches 55 through 57 may be assigned with functions different between the first functional unit 5 and the second functional unit 6, and in that case, in the additional information sending-out period when the second functional unit 6 is operating, the information regarding the on/off state of the switches 55 through 57 is included in the additional information.

### Effects of Electronic Pen according to Embodiment

According to the electronic pen 1 of the embodiment having the configuration described above, when one side in the axial direction of the metal pipe 23 as the tubular coupling member which has a predetermined length in the axial direction is inserted into the coupling side of the front end side case 21 to be coupled with the tail end side case 22 and the other end side of the metal pipe 23 is inserted into the coupling side of the tail end side case 22 to be coupled with the front end side case 21, the front end side case 21 and the tail end side case 22 are coupled and form the pen case 2. Accordingly, the pen case 2 of the electronic pen 1 having the configuration described is obtained by coupling the two members, i.e., the front end side case 21 and the tail end side case 22, but has great resistance to external force in the direction of crossing the axial direction.

Moreover, in a case where the front end side case and the tail end side case both formed of resin are coupled in such a manner as to overlap each other by one of the cases being inserted to the other, if there is tolerance in the configuration of the coupling portion of the two members, stress is applied to the coupling portion and could cause cracks in the coupling portion.

In contrast, the metal pipe 23 is resilient against external power in a direction of crossing the axial direction compared to resin, and has dimensional precision with tight toleration. Further, the metal pipe 23, which has tight toleration for dimensional precision, has an advantage of having smaller stress at the coupling portion between the front end side case 21 and the tail end side case 22.

Further, according to the electronic pen 1 having the configuration described above, even if the coupling member is formed by the metal pipe 23 which is a conductive material, the metal pipe 23 is not in electrical contact with the circuit components provided in the hollow portion of the pen case 2 and the circuit board on which the circuit components are mounted, so that no electrical defects would occur. Further, in the present embodiment, the coupling member including the metal pipe 23 is arranged in such a manner as not to come into contact with the circuit board 7 or the circuit components, so that no extra stress caused by contact would be applied.

### Other Embodiments or Modifications

In the embodiment described above, the metal pipe 23 had a fixed outer diameter, but the portion of the length L1 to be inserted into the front end side case 21 and the portion of the length L2 to be inserted into the tail end side case 22 may have different outer diameters. Moreover, the inner diameter of the metal pipe 23 may similarly be different between the two portions.

Further, in the abovementioned embodiment, the metal pipe 23 is used as the coupling member, but instead, other materials such as hard resin may be used. In that case as well, the coupling member is preferably harder than the front end side case 21 and the tail end side case 22.

Further, in the abovementioned embodiment, the front end side case 21 and the tail end side case 22 had the same outer diameter but instead may have different outer diameters.

Further, in the abovementioned embodiment, the additional information including the information regarding the pressure values detected by the pressure detector 53 and the pressure detector 63 is transmitted through interaction between the first functional unit 5 or the second functional unit 6 and the position detection sensor, but may instead be transmitted to the position detection sensor side through a communication function unit (wired communication function unit) such as a near-field wireless communication unit of a Bluetooth (registered trademark) standard being provided in the electronic pen 1, for example.

Further, in the abovementioned embodiment, the first circuit board section 5CB and the second circuit board section 6CB are provided on a single circuit board 7, but instead, different circuit boards may be used for the first circuit board section 5CB and the second circuit board section 6CB. In that case, different control circuits IC may be used for the first circuit board section 5CB and the second circuit board section 6CB, or as in the example described above, a single common control circuit IC may be provided for one of the first circuit board section 5CB and the second circuit board section 6CB, and connected to the other one of the first circuit board section 5CB and the second circuit board section 6CB by a lead wire or a connection terminal. Note that, even when two circuit boards are to be used, the board holder 8 may be one.

Further, in the abovementioned embodiment, the second functional unit 6 is a writing input erasing functional unit, but the function of the second functional unit 6 is not limited thereto. For example, the second functional unit 6 may be configured as a laser pointer. Moreover, as a function of transmitting information by haptics to a user of the electronic pen 1, the second functional unit 6 may be a haptic information transmitting unit (haptics unit) such as a vibration actuator. Further, the second functional unit 6 may be configured as a motion detection functional unit using a gyro sensor that detects the motion of the electronic pen 1 when the user grips and operates the electronic pen 1. In this case, when the motion output of the electronic pen 1 detected by the motion detection functional unit is to be sent to the position detection sensor side, the motion output may be transmitted as additional information through interaction between the position detection sensor and the first functional unit or through the communication function unit such as the near-field wireless communication unit described above.

Further, the pressure detectors 53 and 63 are configured to detect the pressure as a change in capacitance as the configuration of the variable capacitance capacitor, but may instead be configured to detect the change in inductance or resistance according to the applied pressure.

Moreover, in the abovementioned embodiment, the power supply voltage for the control circuit IC is obtained by rectifying the alternating current energy obtained by electromagnetic induction coupling, but a battery (including a charging-type battery) may be mounted.

Further, in the abovementioned embodiment, the position indication functional unit constituting the first functional unit 5 is configured to interact with the position detection sensor based on an electromagnetic induction system, but may instead be configured to interact with the position detection sensor based on a capacitance system (active capacitance). In that case, when the second functional unit is to be used as the position indication functional unit for erasing, the second functional unit 6 is similarly advantageously configured to interact with the position detection sensor based on a capacitance system (active capacitance). Yet, in a case where a position detection sensor based on an electromagnetic induction system and a position detection sensor based on a capacitance system are to be provided on the position detection sensor side, the electronic pen 1 may have such a configuration in which interaction is made based on different systems between the position indication functional unit of the first functional unit and the second position indication functional unit.

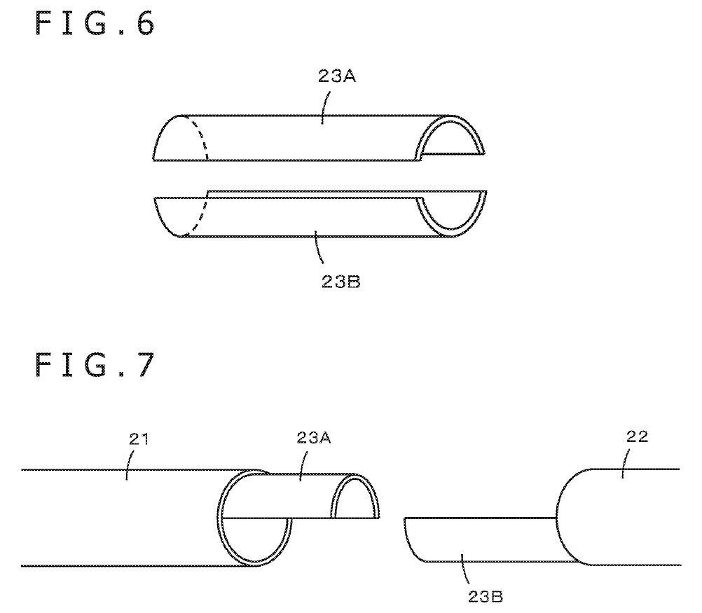

Further, in the abovementioned embodiment, the coupling member is one metal pipe 23, but may instead include a plurality of members obtained by vertically dividing the metal pipe 23, for example. That is, as illustrated in FIG. 6, the metal pipe is vertically divided into two half pipe members 23A and 23B each having a semi-circular arc-shaped cross section. Further, as illustrated in FIG. 7, for example, one half pipe member 23A is inserted and fitted to the front end side case 21, while the other half pipe member 23B is inserted and fitted to the tail end side case 22.

Further, by the one half pipe member 23A of the front end side case 21 being inserted into the tail end side case 22 and the other half pipe member 23B of the tail end side case 22 being inserted into the front end side case 21 to be coupled and form one metal pipe, the front end side case 21 and the tail end side case 22 can be coupled and form the pen case 2.

1. An electronic pen including a pen case formed by a tubular front end side case formed of resin and a tubular tail end side case formed of resin being coupled in an axial direction, the electronic pen comprising:
a first functional unit for position indication provided inside the front end side case;
a second functional unit provided inside the tail end side case; and
a coupling member that has a tubular shape having a predetermined length in an axial direction and has one side in the axial direction being inserted to a coupling side of the front end side case to be coupled with the tail end side case and the other side in the axial direction being inserted to a coupling side of the tail end side case to be coupled with the front end side case to couple the front end side case and the tail end side case together and form the pen case.

2. The electronic pen according to claim 1, wherein, in a hollow portion of the coupling member, circuit components provided in a hollow portion of the pen case and a circuit board on which the circuit components are mounted are located.

3. The electronic pen according to claim 1, wherein the coupling member is in a non-contact state with circuit components provided in a hollow portion of the pen case and a circuit board on which the circuit components are mounted.

4. The electronic pen according to claim 1, wherein the coupling member forms the pen case by being inserted when an outer peripheral side surface having the tubular shape is in contact with an inner wall on the coupling side of the front end side case and an inner wall on the coupling side of the tail end side case and thereby coupling the front end side case and the tail end side case.

5. The electronic pen according to claim 1, wherein
the first functional unit includes a first functional main part and a first circuit board section on which circuit components for the first functional unit are mounted,
the second functional unit includes a second functional main part and a second circuit board section on which circuit components for the second functional unit are mounted, and
the first main part of the first functional unit and the second main part of the second functional unit are disposed at positions not covered by the coupling member, in an axial direction inside the pen case.

6. The electronic pen according to claim 5, wherein
an operator operable by a user is provided on an outer peripheral side surface of the front end side case,
the first circuit board section inside the front end side case includes a switch that is switched according to an operation on the operator, and
the operator and the switch are arranged on a front end side other than a portion at which the coupling member is inserted into the front end side case in an axial direction of the front end side case.

7. The electronic pen according to claim 5, wherein the second functional unit is also used for position indication.

8. The electronic pen according to claim 5, wherein
the first main part of the first functional unit includes a first pressure detector that detects a pressure applied to a front end side, and
the second main part of the second functional unit includes a second pressure detector that detects a pressure applied to a tail end side.

9. The electronic pen according to claim 8, wherein the first pressure detector is configured to be able to perform detection with higher resolution than the second pressure detector.

10. The electronic pen according to claim 8, wherein the first pressure detector is configured to be able to perform detection with higher sensitivity than the second pressure detector.

11. The electronic pen according to claim 5, wherein the coupling member is arranged in such a manner as to cover the circuit components and the circuit board of the second circuit board section.

12. The electronic pen according to claim 5, wherein the first circuit board section and the second circuit board section are arranged on a single circuit board.

13. The electronic pen according to claim 7, wherein a control circuit for controlling the first circuit board section and the second circuit board section is formed on the single circuit board.

14. The electronic pen according to claim 1, wherein an end edge of the coupling side of the front end side case and an end edge of the coupling side of the tail end side case are coupled in a state of being butted against each other.

15. The electronic pen according to claim 8, wherein, when a maximum diameter of a portion of the front end side case in which the first main part of the first functional unit is housed is R1, an inner diameter of the coupling member is R2, and a maximum diameter of a portion of the tail end side case in which the second main part of the second functional unit is housed is R3, R2 > R1 > R3 holds.

16. The electronic pen according to claim 7, wherein
the first main part of the first functional unit and the second main part of the second functional unit each include a coil wound around a magnetic core,
a first capacitor that constitutes a resonant circuit together with the coil of the first functional unit is arranged on the first circuit board section, and
a second capacitor that constitutes a resonant circuit together with the coil of the second functional unit is arranged on the second circuit board section.

17. The electronic pen according to claim 5, wherein
the front end side case has a front end side that is formed to have a tapered shape of gradually tapering off and includes an opening on a front end side, and
a core body having a front end portion protruding outside from the opening is mounted on the first main part of the first functional unit.

18. The electronic pen according to claim 1, wherein the coupling member is formed by a metal pipe.

19. The electronic pen according to claim 1, wherein the coupling member having the tubular shape is formed of a plurality of members obtained by dividing the coupling member in a circumferential direction of the tube shape.

20. The electronic pen according to claim 2, wherein the circuit board is arranged on a boat-shaped board holder.
